(19) United States
(12) Patent Application Publication
(10) Pub. No.: US 2010/0130013 A1
(43) Pub. Date: May 27, 2010

(54) SLURRY COMPOSITION FOR GST PHASE CHANGE MEMORY MATERIALS POLISHING

(75) Inventors: Feng Q. Liu, San Jose, CA (US); Alain Duboust, Sunnyvale, CA (US); Wen-Chiang Tu, Mountain View, CA (US); Chenhao Ge, Sunnyvale, CA (US); Kun Xu, Fremont, CA (US); Yuchun Wang, Santa Clara, CA (US); Yufei Chen, Cupertino, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/622,251

(22) Filed: Nov. 19, 2009

Related U.S. Application Data
(60) Provisional application No. 61/117,525, filed on Nov. 24, 2008.

(51) Int. Cl. H01L 21/306; H01L 21/304; C09K 13/06; C11D 3/20

(52) U.S. Cl. 438/693; 252/79.1; 252/79.4; 510/175; 257/E21.23

(57) ABSTRACT

A CMP method for polishing a phase change alloy on a substrate surface including positioning the substrate comprising a phase change alloy material on a platen containing a polishing pad and delivering a polishing slurry to the polishing pad. The polishing slurry includes colloidal particles with a particle size less than 60 nm, in an amount between 0.2% to about 10% by weight of slurry, a pH adjustor, a chelating agent, an oxidizing agent in an amount less than 1% by weight of slurry, and polyacrylic acid. The substrate on the platen is polished to remove a portion of the phase change alloy. A rinsing solution for rinsing the substrate on the platen includes deionized water and at least one component in the deionized water where the component selected from the group consisting of polyethylene imine, polyethylene glycol, polyacrylic amide, alcohol ethoxylates, polyacrylic acid, an azole containing compound, benzo-triazole, and combinations thereof.

### CROSS-REFERENCE TO RELATED APPLICATIONS

This application claims benefit of U.S. provisional patent application Ser. No. 61/117,525, filed Nov. 24, 2008, which is herein incorporated by reference.

### BACKGROUND OF THE INVENTION

1. Field of the Invention

Embodiments of the present invention generally relate to polishing compositions and methods for polishing a substrate using the same. More particularly, embodiments of the invention relate to chemical-mechanical polishing compositions suitable for polishing substrates comprising phase change alloys.

2. Description of the Related Art

Typical solid state memory devices (dynamic random access memory (DRAM), static random access memory (SRAM), erasable programmable read only memory (EPROM), and electrically erasable programmable read only memory (EEPROM)) employ micro-electronic circuit elements for each memory bit in memory applications. Since one or more electronic circuit elements are required for each memory bit, these devices consume considerable chip space to store information, limiting chip density. For typical non-volatile memory elements (like EEPROM i.e. “flash” memory), floating gate field effect transistors are employed as the data storage device. These devices hold a charge on the gate of the field effect transistor to store each memory bit and have limited re-programmability. They are also slow to program.

PRAM (Phase Change Random Access Memory) devices (also known as Ovonic memory devices) use phase change materials that can be electrically switched between an insulating amorphous and conductive crystalline state for electronic memory application. Typical materials suited for these applications utilize various chalcogenide (Group VIB) and Group VB elements of the periodic table (e.g., Te, Po, and Sb) in combination with one or more of In, Ge, Ga, Sn, or Ag (sometimes referred to herein as a “phase change alloy”). Particularly useful phase change alloys are germanium (Ge)-antimony (Sb)-tellurium (Te) alloys (GST alloys), such as an alloy having the formula Ge₂ Sb₂ Te₅. These materials can reversibly change physical states depending on heating/cooling rates, temperatures, and times. Other useful phase change material alloys include indium antimonite (InSb). The memory information in PRAM is preserved with minimal loss through the conductive properties of the different physical states.

Chemical-Mechanical Polishing (CMP) techniques can be utilized to manufacture memory devices employing phase change materials. However, current CMP slurry, rinse, etc. compositions do not provide sufficient planarity when utilized for polishing substrates having relatively soft phase change alloys, such as a GST alloy. In particular, the physical properties of many phase change alloys (e.g., GST or InSb) make them “soft” relative to other materials utilized in phase-change memory (PCM) chips. For example, typical CMP polishing slurries containing relatively high solid concentrations (>about 3%) remove a phase change alloy (e.g., a GST alloy) through the mechanical action of the abrasive particles resulting in heavy scratching on the surface of the phase change alloy. When such high solids CMP compositions are used, phase change alloy residues often remain on the underlying dielectric film after polishing, since the CMP slurry is not able to remove all of the phase change alloy material. The phase change alloy residues cause further integration issues in subsequent steps of device manufacturing. Additionally, even removal of a multi-component alloy poses a challenge for conventional CMP techniques.

Thus, there is an ongoing need to develop new CMP compositions that provide reduced scratching and residue defects, while still providing acceptably rapid removal of phase change alloys compared to conventional CMP compositions.

### SUMMARY OF THE INVENTION

One embodiment of the invention generally provides chemical-mechanical polishing (CMP) slurry for removing at least a phase change alloy from a substrate surface. The slurry includes colloidal particles with a particle size less than 60 nm and in an amount between 0.2% to about 10% by weight of the slurry, a pH adjustor, a chelating agent comprising at least one organic carboxylic acid, an oxidizing agent in an amount less than 1% by weight of the slurry, and polyacrylic acid.

Another embodiment of the invention also provides a rinse solution for passivation of a phase change alloy on a substrate surface used in conjunction with CMP polishing of the phase change alloy. The rinse solution includes deionized water and at least one component in the deionized water selected from the group comprising polyethylene glycol, polyacrylic amide, polyethylene imine, an azole containing compound, benzo-triazole, and combinations thereof. The rinse solution has a pH between 2 and 12.

In yet another embodiment of the invention, a method for chemical-mechanical polishing (CMP) of a phase change alloy on a substrate surface is provided. The method includes positioning a substrate comprising a phase change alloy material on a platen containing a polishing pad in a polishing slurry, polishing the substrate on the platen to remove a portion of the phase change alloy, and rinsing the substrate on the platen with a rinse solution. The polishing slurry includes colloidal particles with a particle size less than 60 nm and in an amount between 0.2% to about 10% by weight of the slurry, a pH adjustor, a chelating agent comprising at least one carboxylic acid, an oxidizing agent in an amount less than 1% by weight of the slurry, and polyacrylic acid. The rinse solution used in the method includes deionized water and at least one component in the deionized water selected from the group comprising polyethylene glycol, polyacrylic amide, polyethylene imine, an azole containing compound, benzo-triazole, and combinations thereof. The rinse solution has a pH between 2 and 12.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a chalcogenide semiconductor having a phase change alloy.

FIG. 2 shows a chemical mechanical polishing apparatus that may be used to polish a phase change alloy containing substrate.

FIG. 3 is a partial sectional view of one embodiment of a polishing station that includes a fluid delivery arm assembly.

FIGS. 4A-4C are schematic cross-sectional views illustrating a polishing process performed on a phase change alloy containing substrate according to one embodiment of the invention.

FIG. 5 is a flow diagram of one embodiment of a method for chemical mechanical polishing a phase change alloy containing substrate.

### DETAILED DESCRIPTION

Embodiments of the invention relate to chemical mechanical planarization or chemical mechanical polishing (CMP) of phase change alloys. Phase change memory devices may employ in their memory cells a phase change layer (a chalcogenide semiconductor thin film or the like) whose electrical resistance changes depending on its state. Chalcogenide semiconductors are amorphous semiconductors including chalcogen elements.

Chalcogen elements include S (Sulfur), Se (Selenium), and Te (Tellurium) in group VI in the periodic table. Chalcogenide semiconductors are used in generally two fields, optical disks and electric memories. Chalcogenide semiconductors used in the field of electric memories include Ge₂Sb₂Te₅ (hereinafter referred to as “GST”) which is a compound of Ge (Germanium), Te (Tellurium), and Sb (Antimony).

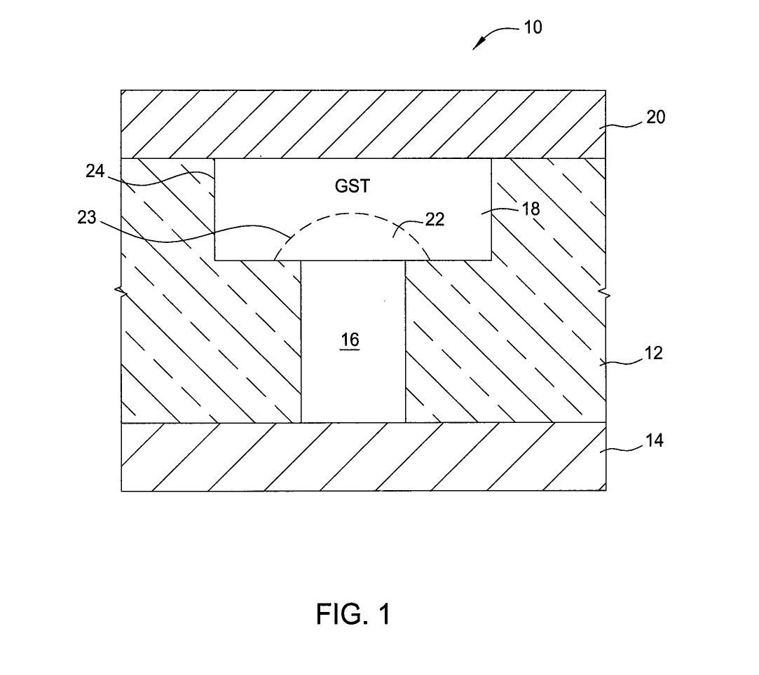

An example of a phase-change memory (PCM) cell 10 is illustrated in the cross-sectional view of FIG. 1 although embodiments of PCM cells are not limited to such a structure. A dielectric layer 12, for example silicon oxide, is grown over a bottom electrode 14. A vertical structure is etched through the dielectric layer 12. A via 16 in the lower portion is filled with a metal to contact the bottom electrode 14. A wider plug 18 at the top of the dielectric layer 12 and contacting and overhanging the via 16 is filled with a phase change alloy, such as the metal chalcogenide germanium antimony telluride (GST). A top electrode 20 is deposited over the GST plug 18.

As shown in FIG. 1, a chalcogenide semiconductor can take two stable states, i.e., amorphous state 23 and crystalline state 24. In operation, a short electrical pulse is applied through the electrodes 14, 20 to the GST plug 18 to cause a phase-change region 22 to melt. The remainder of the GST plug 18 is preferably always in the conductive crystalline state 24. Depending on whether the melting pulse is short or long, the phase-change region 22 either quickly cools and quenches to a high-resistance amorphous state 23 or slowly cools to a low-resistance crystalline state 24. The state of the PCM cell 10 can be read by measuring its resistance between the electrodes 14, 20 across the GST plug.

The amorphous state exhibits a higher electrical resistance corresponding to a digital value “1” and the crystalline state exhibits a lower electrical resistance corresponding to a digital value “0”. This allows the chalcogenide semiconductor to store digital information. The amount of current flowing through the chalcogenide semiconductor or a voltage drop across the chalcogenide semiconductor is detected to determine whether the information stored in the chalcogenide semiconductor is “1” or “0”.

Specifically, after the chalcogenide semiconductor is supplied with heat at a temperature near its melting point, it switches into the amorphous state when the chalcogenide semiconductor is quickly cooled. After the chalcogenide semiconductor is supplied with heat at a crystallizing temperature lower than the melting point for a long period of time, it switches into the crystalline state when the chalcogenide semiconductor is cooled. For example, after the GST is supplied with heat at a temperature near the melting point (about 610° C.) for a short period of time (1 through 10 ns), it switches into the amorphous state when the GST is quickly cooled for about 1 ns. After the GST is supplied with heat at a crystallizing temperature (about 450° C.) for a long period of time (30 through 50 ns), it switches into the crystalline state when the GST is cooled.

Switching currents may be reduced by a variation of the structure of FIG. 1 in which a smaller volume of GST is deposited near the bottom of the via 16 and the metal fills the rest of the via and the phase-change region 22.

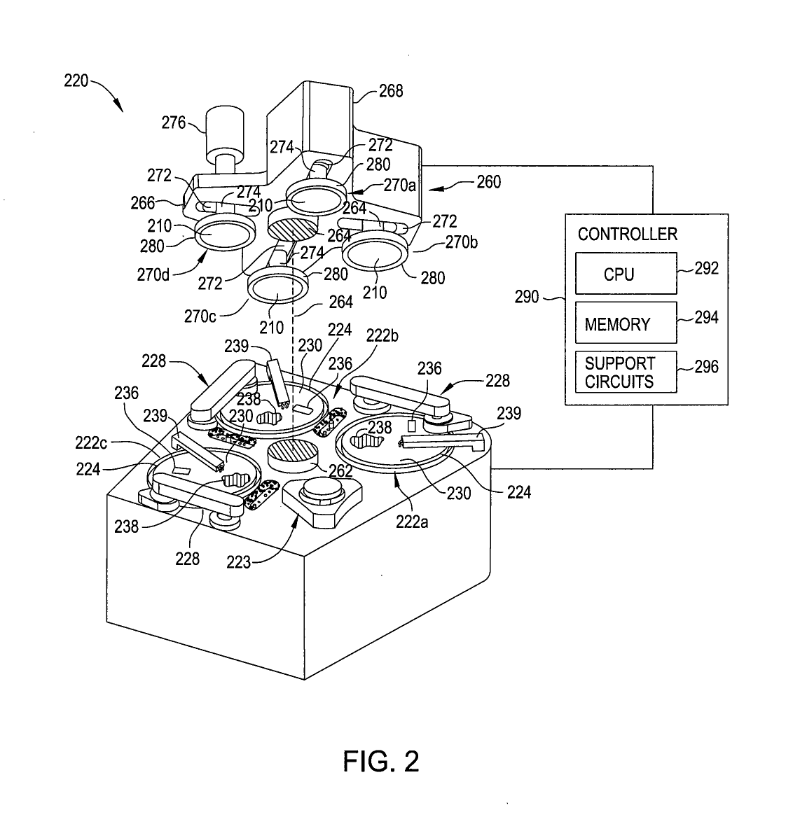

FIG. 2 shows a chemical mechanical polishing apparatus that may be used to polish a phase change alloy containing substrate. While the particular apparatus in which the embodiments described herein can be practiced is not limited, it is particularly beneficial to practice the embodiments in a REFLEXION® CMP system, REFLEXION® LK CMP system, and a MIRRA MESA® system sold by Applied Materials, Inc., Santa Clara, Calif. Additionally, CMP systems available from other manufacturers may also benefit from embodiments described herein. Although a CMP system is depicted for using embodiments of the invention, an electrochemical mechanical polishing system (eCMP) may also be suited to use embodiments of the invention.

FIG. 2 shows a chemical mechanical polishing apparatus 220 that can polish one or more substrates 210 such as wafers. Polishing apparatus 220 includes a series of polishing stations 222 and a transfer station 223. Transfer station 223 transfers the substrates between carrier head assemblies 270 and a loading apparatus (not shown).

Each polishing station 222 includes a rotatable platen assembly 224 on which is placed a polishing pad assembly 230. The first and second stations 222 can include a two-layer polishing pad with a hard durable outer surface or a fixed-abrasive pad with embedded abrasive particles. The final polishing station 222 can include a relatively soft pad. Each polishing station 222 can also include a pad conditioner apparatus 228 to maintain the condition of the polishing pad assembly 230 so that it will effectively polish substrates 210.

A rotatable multi-head carousel 260 supports four carrier head assemblies 270. The carousel 260 is rotated by a central post 262 about a carousel axis 264 by a carousel motor assembly (not shown) to orbit the carrier head assembly 270 and the substrates 210 attached thereto between polishing stations 222 and transfer station 223. Three of the carrier head assemblies 270 receive and hold substrates 210, and polish them by pressing them against the polishing pad assemblies 230. Meanwhile, one of the carrier head assemblies 270 receives a substrate 210 from and delivers a substrate 210 to the transfer station 223.

Each carrier head assembly 270 is connected by a carrier drive shaft 274 to a carrier head rotation motor 276 (shown by the removal of one quarter of cover 268 so that each carrier head can independently rotate about its own axis). In addition, each carrier head assembly 270 independently laterally oscillates in a radial slot 272 formed in carousel support plate 266.

Slurry 238 is supplied to the surface of the polishing pad assembly 230 by a slurry supply port or combined slurry/rinse arm assembly 239. The slurry 238 includes colloidal particles, a pH adjustor, a chelating agent comprising at least one organic carboxylic acid, an oxidizing agent in an amount less than 1% by weight of the slurry, and polyacrylic acid. In one embodiment, the slurry contains organic carboxylic acid in an amount of 0.1% to 3.0% by weight of the slurry, an oxidizing agent in an amount of 0.1% to 3.0% by weight of the slurry, and polyacrylic acid in an amount between 50 ppm and 5000 ppm. The slurry may also be adjusted to have a pH level between about 2 and about 9, such as between a pH of about 7 and about 9, between a pH of about 3 and about 6, or between a pH of about 2 and about 7. The oxidizing agent may comprise at least one of the following: hydrogen peroxide, organic peroxide, potassium iodate, and ammonium persulfate. The pH adjustor may comprise KOH or NH₄OH added to the slurry in an amount sufficient to adjust the pH to be within any of the above ranges.

Colloidal particles used with embodiments of this invention may be any particles suitable for use as an abrasive. The colloidal particles have a particle size less than 60 nm and are in an amount between 0.1% to about 10% by weight of the slurry. The colloidal particles may be between 10-30 nm in size. In another embodiment, the colloidal particles may be between about 5-85 nm in size. The colloidal particles that may be used include, but are not limited to, silica, alumina, modified silica with alumina, surface coated alumina-silica, or surface modified silica with organic groups. For example, colloidal silica may be positively activated, such as with an alumina modification or a silica/alumina composite. In the embodiment where the colloidal particles are silica with alumina or surface coated alumina, the pH may be between 3 and 7, such as between 5 and 7.

The organic carboxylic acid may include, but is not limited to citric acid, tartaric acid, succinic acid, oxalic acid, amino acids, salts thereof, or combinations thereof. For example, suitable salts for the chelating agent may include ammonium citrate, potassium citrate, ammonium succinate, potassium succinate, ammonium oxalate, potassium oxalate, potassium tartrate, or combinations thereof. The salts may have multi-basic states, for example, citrates have mono-, di- and tri-basic states. Other suitable chelating agents may include acetic acid, adipic acid, butyric acid, capric acid, caproic acid, caprylic acid, glutaric acid, glycolic acid, formaic acid, fumaric acid, lactic acid, lauric acid, malic acid, maleic acid, malonic acid, myristic acid, palmitic acid, phthalic acid, propionic acid, pyruvic acid, stearic acid, valeric acid, derivatives thereof, salts thereof or combinations thereof. Suitable chelating agents may be free of an amine or amide functional groups. The organic carboxylic acid is added to the slurry in an amount between 0.1% and 3.0% by weight of the slurry.

The polishing slurry may also include an inorganic acid for providing a suitable pH. Suitable acids include, for example, phosphoric acids, sulfuric acid, nitric acid, perchloric acid, or combinations thereof. In one embodiment, the slurry may contain H₃PO₄ in an amount between 50 ppm to 5000 ppm. The acid may also buffer the composition to maintain a desired pH level for processing a substrate. For example, the slurry may have a desired pH level between 3 and 7, such as between 3 and 6 or between 5 and 7.

Examples of suitable acids include compounds having a phosphate group (PO₄³⁻), such as, phosphoric acid, copper phosphate, potassium phosphates (KₓH₍₃₋ₓ₎PO₄) (x=1, 2 or 3), such as potassium dihydrogen phosphate (KH₂PO₄), dipotassium hydrogen phosphate (K₂HPO₄), ammonium phosphates ((NH₄)ₓH₍₃₋ₓ₎PO₄) (x=1, 2 or 3), such as ammonium dihydrogen phosphate ((NH₄)H₂PO₄), diammonium hydrogen phosphate ((NH₄)₂HPO₄), compounds having a nitrite group (NO₃¹⁻), such as, nitric acid or copper nitrate, compounds having a boric group (BO₃³⁻), such as, orthoboric acid (H₃BO₃) and compounds having a sulfate group (SO₄²⁻), such as sulfuric acid (H₂SO₄), ammonium hydrogen sulfate ((NH₄)HSO₄), ammonium sulfate, potassium sulfate, copper sulfate, derivatives thereof or combinations thereof.

A clear window 236 is included in the polishing pad assembly 230 and is positioned such that it passes beneath substrate 210 during a portion of the platen's rotation, regardless of the translational position of the carrier head. The clear window 236 may be used for metrology devices, for example, an eddy current sensor and a laser may be placed below the clear window 236. In certain the window 236 and related sensing methods may be used for an endpoint detection process.

To facilitate control of the polishing apparatus 220 and processes performed thereon, a controller 290 comprising a central processing unit (CPU) 292, memory 294, and support circuits 296, is connected to the polishing apparatus 220. The CPU 292 may be one of any form of computer processor that can be used in an industrial setting for controlling various drives and pressures. The memory 294 is connected to the CPU 292. The memory 294, or computer-readable medium, may be one or more of readily available memory such as random access memory (RAM), read only memory (ROM), floppy disk, hard disk, or any other form of digital storage, local or remote. The support circuits 296 are connected to the CPU 292 for supporting the processor in a conventional manner. These circuits include cache, power supplies, clock circuits, input/output circuitry, subsystems, and the like.

The polishing station 222 includes a combined slurry/rinse arm assembly 239. During polishing, the arm 330 is operable to dispense slurry 238 containing a liquid and a pH adjuster. Alternatively, the polishing station includes a slurry port operable to dispense slurry onto polishing pad assembly 230.

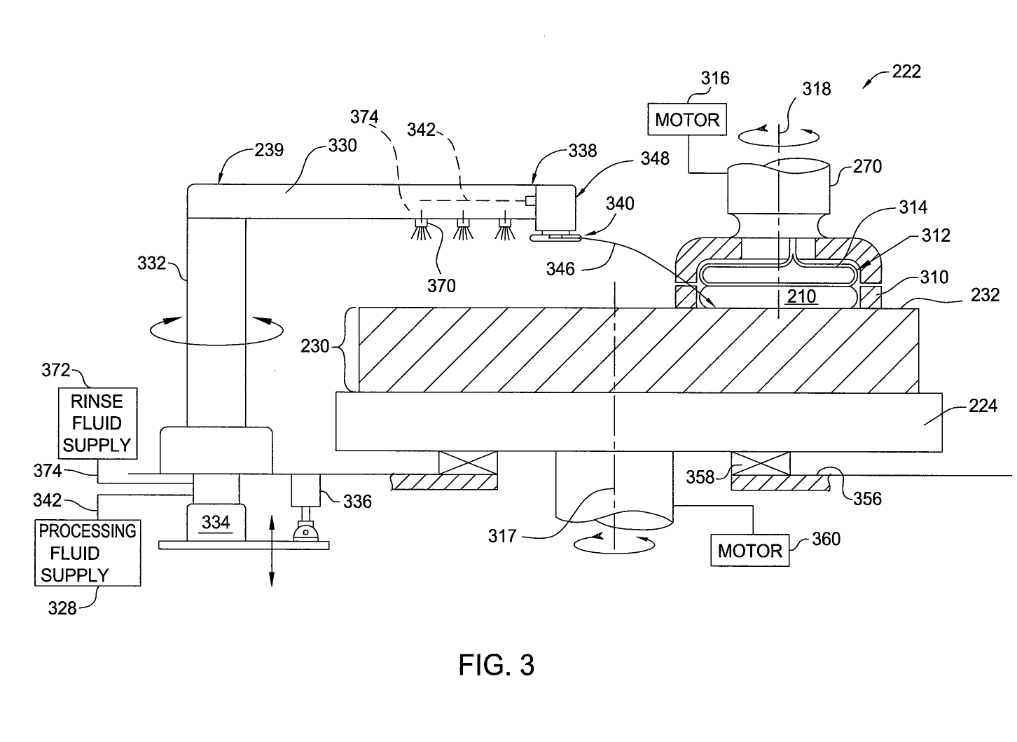

With reference to FIGS. 2 and 3, the polishing station 222 includes a carrier head assembly 270 operable to hold the substrate 210 against the polishing pad assembly 230. The carrier head assembly 270 is suspended from a support structure, for example, the carousel 260, and is connected by a carrier drive shaft 274 to a carrier head rotation motor 276 so that the carrier head can rotate about an axis 318. In addition, the carrier head assembly 270 can oscillate laterally in a radial slot 272 formed in the support structure. In operation, the platen assembly 224 is rotated about its central axis 317, and the carrier head assembly 270 is rotated about its central axis 318 and translated laterally across an upper surface 232 (see FIG. 3) of the polishing pad assembly 230.

FIG. 3 is a partial sectional view of one of the polishing stations 222 that includes the combined slurry/rinse arm assembly 239. The polishing station 222 includes the carrier head assembly 270 and a platen assembly 224. The carrier head assembly 270 generally retains the substrate 210 against a polishing pad assembly 230 disposed on the platen assembly 224. At least one of a carrier head assembly 270 or platen assembly 224 is rotated or otherwise moved to provide relative motion between the substrate 210 and the polishing pad assembly 230. In the embodiment depicted in FIG. 3, the carrier head assembly 270 is coupled to an actuator or motor 316 that provides at least rotational motion to the substrate 210. The motor 316 may also oscillate the carrier head assembly 270, such that the substrate 210 is moved laterally back and forth across the surface of the polishing pad assembly 230.

The polishing pad assembly 230 may comprise a conventional material such as a foamed polymer disposed on the platen assembly 224 as a pad. In one embodiment, the conventional polishing material is foamed polyurethane. In one embodiment, the pad is an IC1010 polyurethane pad, available from Rodel Inc., of Newark, Del. IC1010 polyurethane pads typically have a thickness of about 2.05 mm and a compressibility of about 2%. Other pads that can be used include IC1000 pads with and without an additional compressible bottom layer underneath the IC1000 pad, IC1010 pads with an additional compressible bottom layer underneath the IC1010 pad, and polishing pads available from other manufacturers. The compositions described herein are placed on the pad to contribute to the chemical mechanical polishing of substrate.

In one embodiment, the carrier head assembly 270 includes a retaining ring 310 circumscribing a substrate receiving pocket 312. A bladder 314 is disposed in the substrate receiving pocket 312 and may be evacuated to chuck the wafer to the carrier head assembly 270 and pressurized to control the downward force of the substrate 210 when pressed against the polishing pad assembly 230. In one embodiment, the carrier head may be a multi-zone carrier head. One suitable carrier head assembly 270 is a TITAN HEAD™ carrier head available from Applied Materials, Inc., located in Santa Clara, Calif.

In FIG. 2, the platen assembly 224 is supported on a base 356 by bearings 358 that facilitate rotation of the platen assembly 224. A motor 360 is coupled to the platen assembly 224 and rotates the platen assembly 224 such that the polishing pad assembly 230 is moved relative to the carrier head assembly 270.

The combined slurry/rinse arm assembly or fluid delivery arm assembly 239 is utilized to deliver slurry from a slurry supply 328 to a top or working surface of the polishing pad assembly 230. In the embodiment depicted in FIG. 3, the fluid delivery arm assembly 239 includes an arm 330 extending from a stanchion 332. A motor 334 is provided to control the rotation of the arm 330 about a center line of the stanchion 332. An adjustment mechanism 336 may be provided to control the elevation of a distal end 338 of the arm 330 relative to the working surface of the polishing pad assembly 230. The adjustment mechanism 336 may be an actuator coupled to at least one of the arm 330 or the stanchion 332 for controlling the elevation of the distal end 338 of the arm 330 relative to the platen assembly 224.

The fluid delivery arm assembly 239 may include a plurality of rinse outlet ports 370 arranged to uniformly deliver a spray and/or stream of rinsing fluid to the surface of the polishing pad assembly 230. The ports 370 are coupled by a tube 374 routed through the fluid delivery arm assembly 239 to a rinsing fluid supply 372. In one embodiment, the fluid delivery arm may have between 12 and 15 ports. The rinsing fluid supply 372 provides a rinsing fluid to the polishing pad assembly 230 before, during, and/or after polishing the phase change alloy containing substrate and/or after the substrate 210 is removed to clean the polishing pad assembly 230. The polishing pad assembly 230 may also be cleaned using fluid from the ports 370 after conditioning the pad using a conditioning element, such as a diamond disk or brush (not shown).

The rinsing fluid may be used for passivation of a phase change alloy on a substrate surface used in conjunction with CMP polishing of the phase change alloy. The rinse solution includes deionized water and at least one component in the deionized water. The component is selected from the group consisting of polyethylene imine, polyethylene glycol, polyacrylic amide, alcohol ethoxylates polyacrylic acid, an azole containing compound, benzo-triazole, and combinations thereof. Examples of organic compounds having azole groups include benzotriazole (BTA), mercaptobenzotriazole, 5-methyl-1-benzotriazole (TTA), tolyltriazole (TTA), 1,2,4 triazole, benzoylimidazole (BIA), benzimidazole, derivatives thereof or combinations thereof.

The rinse solution may be formed by mixing 10 to 14 liters of deionized water with 300 milliliters of a 1%-10% component solution i.e. the component solution has 1% to 10% of component by weight. The rinse solution has a pH between 2 and 12. In one embodiment, the pH range is between a pH of about 2 and about 7.5.

The nozzle assembly 348 is disposed at the distal end of the arm 330. The nozzle assembly 248 is coupled to the slurry supply 328 by a tube 342 routed through the fluid delivery arm assembly 239. The nozzle assembly 348 includes a nozzle 340 that may be selectively adjusted relative to the arm, such that the fluid exiting the nozzle 340 may be selectively directed to a specific area of the polishing pad assembly 230.

In one embodiment, the nozzle 340 is configured to generate a spray of slurry. In another embodiment, the nozzle 340 is adapted to provide a stream of slurry. In another embodiment, the nozzle 340 is configured to provide a stream and/or spray of slurry 346 at a rate between about 200 to about 500 ml/second to the polishing surface.

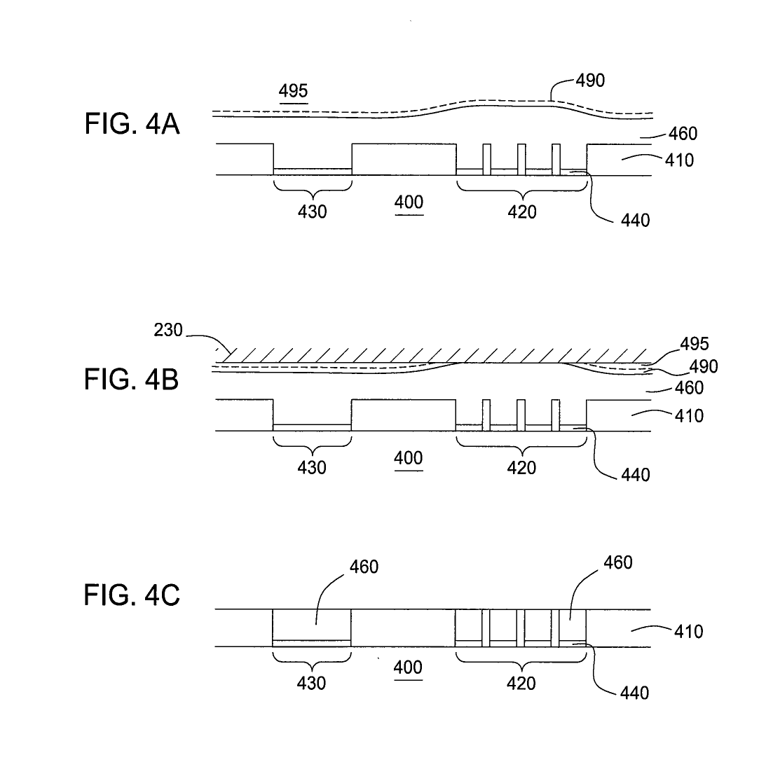

One embodiment of the process will now be described in reference to FIGS. 4A-4C, which are schematic cross-sectional views of a substrate being processed according to methods and compositions described herein. Referring to FIG. 4A, a substrate generally includes a dielectric layer 410 formed on a substrate 400. A plurality of apertures, such as vias, trenches, contacts, or holes, are patterned and etched into the dielectric layer 410, such as a dense array of narrow feature definitions 420 and low density of wide feature definitions 430. The apertures may be formed in the dielectric layer 410 by conventional photolithographic and etching techniques.

FIG. 4A depicts a substrate 400 and a phase change alloy 460 with a passivation layer 490 formed thereon after using the rinse described above. FIG. 4B illustrates the contact of the substrate surface with a polishing article to remove a portion of a passivation layer 490 formed thereon and the underlying phase change alloy 460. FIG. 4C illustrates the substrate after a portion of the phase change alloy 460 on the dielectric layer 410 has been removed by applying a CMP process using the slurry described above. Alternatively, and not shone, the phase change alloy 460 may be removed in multiple processing steps.

The dielectric layer 410 may comprise one or more dielectric materials conventionally employed in the manufacture of semiconductor devices. For example, dielectric materials may include materials such as silicon dioxide, phosphorus-doped silicon glass (PSG), boron-phosphorus-doped silicon glass (BPSG), and silicon dioxide derived from tetraethyl orthosilicate (TEOS) or silane by plasma enhanced chemical vapor deposition (PECVD). The dielectric layer may also comprise low dielectric constant materials, including fluoro-silicon glass (FSG), polymers, such as polyamides, carbon-containing silicon oxides, such as BLACK DIAMOND® dielectric material, silicon carbide materials, which may be doped with nitrogen and/or oxygen, including BLOk® dielectric materials, available from Applied Materials, Inc. of Santa Clara, Calif. The dielectric layer may also include SiN.

A phase change alloy 460 is disposed on the dielectric layer 410 and in the vias, trenches, contacts, or holes. The phase change alloy 460 may comprise chalcogen elements such as GST. The CMP process may begin by positioning the substrate in a polishing apparatus and exposing the substrate to a rinse solution 495 that can form a passivation layer 490 on the phase change alloy 460. The passivation layer 490 may be formed by the rinse solution described herein.

FIG. 4B illustrates chemical mechanical polishing during processing. During processing, the substrate surface and a polishing pad assembly 230 are contacted with one another and moved in relative motion to one another, such as in a relative orbital motion, to remove portions of the passivation layer 490 formed on the exposed phase change alloy 460, which may additionally remove a portion of the underlying phase change alloy 460. A view of the final planarized substrate surface containing the phase change alloy 460, as depicted in FIG. 4C, is formed by using the polishing slurry and rinse described above and according to the methods disclosed herein.

The substrate surface and polishing pad assembly 230 are contacted at pressure less than about 2.5 pounds per square inch (lb/in² or psi). Removal of the passivation layer 490 and some phase change alloy 460 may be performed with a process having a pressure of about 2 psi or less, for example, from about 0.3 psi to about 2.2 psi. In one aspect of the process, the substrate surface and polishing article are contacted at a pressure of about 1 psi or less. In one embodiment, the CMP process may have a pressure between about 0.5 psi to 1.5 psi.

In one embodiment the platen is rotated at a velocity from about 20 rpm (rotations per minute) to about 120 rpm, and the polishing head is rotated at a velocity from about 20 rpm to about 120 rpm and also moved linearly at a velocity from about 0.3 cm/s (centimeters per second) to about 3 cm/s in a direction radial to the platen. The preferred ranges for a 300 mm diameter substrate are a platen rotational velocity from about 40 rpm to about 100 rpm and a polishing head rotational velocity from about 40 rpm to about 100 rpm and a linear (e.g., radial) velocity of about 2 cm/s. A removal rate of phase change alloy of between about 100 nm/min to about 145 nm/min can be achieved by the processes described herein. A down force pressure of 0.5 psi to 1.0 psi may also be used to vary the removal rate.

Optionally, a rinse solution may be applied to the substrate after the polishing process to remove particulate matter and spent reagents from the polishing process as well as help minimize metal residue deposition on the polishing articles and defects formed on a substrate surface. The rinse solution includes deionized water and at least one component in the deionized water. The component is selected from the group consisting of polyethylene imine, polyethylene glycol, polyacrylic amide, alcohol ethoxylates, polyacrylic acid, an azole containing compound, benzo-triazole, and combinations thereof. The rinse solution has a pH between 2 and 12. For example, the rinse solution may be formed by mixing 10 to 14 liters of deionized water with 300 milliliters of a 1-10% component solution.

In one embodiment of the invention, the slurry has a particle size of about 50 nm. The slurry is modified by adding polyacrylic amide or other polymers from 0.1%-0.5% by weight. The modified slurry may be diluted with deionized water in a ratio of 1:0 to 1:9. In this embodiment, the removal rate may be from 400 Å/min to 2000 Å/min with a down force from 0.5 psi to 2 psi. In another embodiment of the invention, the slurry may be a commercially available slurry that is modified according to the above conditions. One example of a commercially available slurry from Cabot Microelectronics located in Aurora, Ill. is iCue® EP-C7092.

After polishing, some stains may remain on the polishing pad, which may be byproducts of the GST alloy on the pad. To prevent unwanted particulate transfer from pad to other substrates, a pad cleaning solution may be used. The pad cleaning solution is phosphoric acid based with about 0.2%-2.0% of phosphoric acid and about 0.2%-10% hydrogen peroxide. Other organic acids may also be added such as citric acid at 0.1%-2.0%. Using a pad cleaning solution as described, the stains may be removed from the pad in about one minute.

The pad cleaning solution may be applied between every wafer polishing or between multiple wafers polishing. In one embodiment, the pad cleaning solution is delivered onto the pad while the pad slowly rotates at 20 rpm or less, for example at about 5 rpm. The pad is soaked for about 30 seconds and then conditioned for about 20 seconds. After which, the pad is rinsed for 5 seconds with deionized water at a fast rotation of the platen or pad at 80 rpm or more, for example at about 100 rpm.

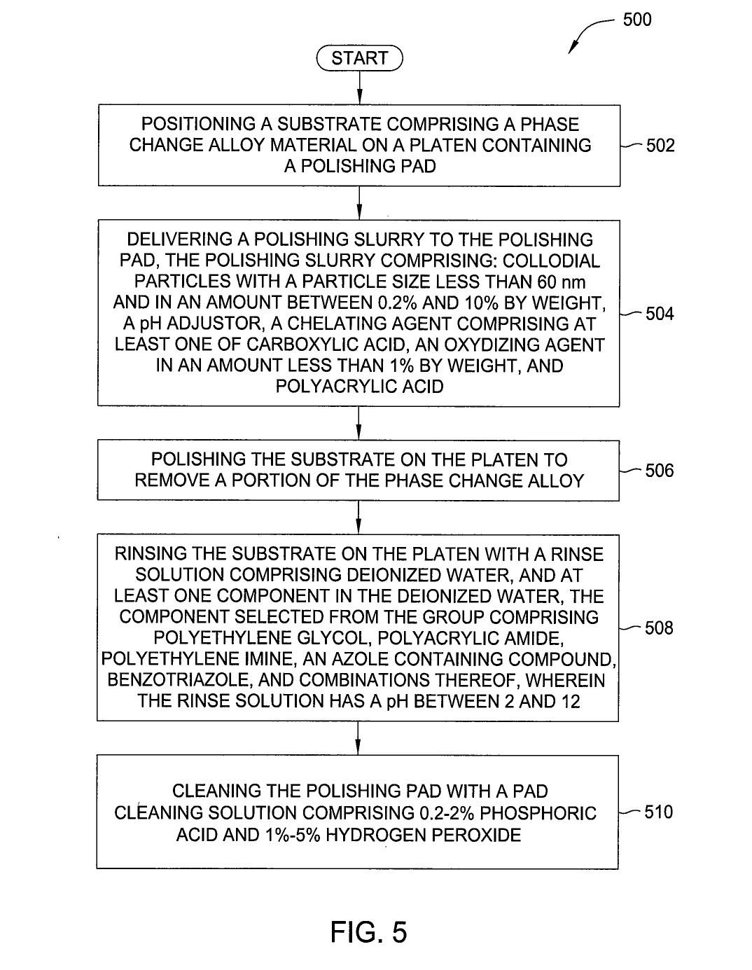

Referring to FIG. 5, a flow chart of one embodiment of the polishing method 500 is described herein. A substrate is positioned on a platen containing a polishing pad (box 502). The substrate has a phase change alloy material disposed thereon, such as GST. A polishing slurry is delivered to the polishing pad (box 504) where the polishing slurry comprises colloidal particles with a particle size less than 60 nm and in an amount between 0.2% and 10% by weight of the slurry, a pH adjustor, a chelating agent comprising at least one carboxylic acid, an oxidizing agent in an amount less than 1% by weight of the slurry, and polyacrylic acid.

The slurry may also include H₃PO₄ in an amount between 50 ppm to 5000 ppm. In one embodiment, the slurry includes colloidal particles such as silica, alumina, modified silica with alumina, surface coated alumina-silica, or surface modified silica with organic groups. In embodiments that have surface modified alumina or modified silica, the pH may be between 6 and 7. In another embodiment, the polyacrylic acid is in an amount between 50 ppm and 5000 ppm. The carboxylic acid is chosen from the group consisting of citric acid, oxalic acid, tartaric acid, and succinic acid, or combinations thereof. The polishing slurry may include any of the embodiments described herein.

The substrate on the platen is then polished to remove a portion of the phase change alloy (box 506). A rinse solution is used to rinse the substrate on the platen (box 508). The rinse duration may be between 5 and 30 seconds. The rinse solution includes deionized water and at least one component in the deionized water selected form the group comprising polyethylene glycol, polyacrylic amide, polyethylene imine, an azole containing compound, benzo-triazole, and combinations thereof. In some embodiments, two or more components may be used in the rinse solution. The rinse solution has a pH between 2 and 12 and 300 milliliters of the component may be mixed in 10 to 14 liters of deionized water. Rinsing the substrate may be performed before, during, or after polishing the substrate.

In another embodiment, a pad cleaning solution may be used to clean any stains remaining on the polishing pad after polishing the phase change alloy (box 510). The cleaning solution is delivered onto the pad at a slow pad rotation followed by soaking the pad for 30 seconds with the pad cleaning solution. Next, the pad is conditioned for 30 seconds, and rinsed with deionized water for about 5 seconds at a fast rotation of the platen. Cleaning the polishing pad may be between about 30 seconds and about 90 seconds. The pad cleaning may include 0.2-2% phosphoric acid and 0.2%-5% hydrogen peroxide, such as a 1% hydrogen peroxide solution. Further, 0.1%-2.0% citric acid may also be added to the cleaning solution.

It has been observed that substrate planarized by the processes described herein have exhibited reduced topographical defects, such as dishing, reduced residues, improved planarity, and improved substrate finish. According to embodiments of the invention, a 50% decrease in defects was observed.

While the foregoing is directed to embodiments of the present invention, other and further embodiments of the invention may be devised without departing from the basic scope thereof, and the scope thereof is determined by the claims that follow.

1. A chemical-mechanical polishing (CMP) slurry for removing at least a phase change alloy from a substrate surface, the slurry initially comprising:
colloidal particles with a particle size less than 60 nm and in an amount between 0.2% to about 10% by weight of the slurry;
a pH adjustor;
a chelating agent comprising at least one organic carboxylic acid;
an oxidizing agent in an amount less than 1% by weight of the slurry; and
polyacrylic acid.

2. The slurry of claim 1, wherein the polyacrylic acid is in an amount between 50 ppm and 5000 ppm.

3. The slurry of claim 1, wherein the colloidal particles are selected from the group consisting of silica, alumina, or combinations thereof.

4. The slurry of claim 3, wherein the colloidal particles are modified silica with alumina, surface coated alumina-silica, or surface modified silica with organic groups.

5. The slurry of claim 4, wherein the slurry has a pH between 5 and 7.

6. The slurry of claim 1, wherein the slurry has a pH between 3 and 9.

7. The slurry of claim 1, wherein the colloidal particle size is in the range between 10 nm and 50 nm.

8. The slurry of claim 1 further comprising H₃PO₄ in an amount between 50 ppm to 5000 ppm.

9. The slurry of claim 1, wherein the organic carboxylic acid is selected from the group consisting of citric acid, oxalic acid, tartaric acid, and succinic acid, amino acids, salts thereof, and combinations thereof.

10. The slurry of claim 1, wherein the oxidizing agent comprises at least one of the following: hydrogen peroxide, organic peroxide, potassium iodate, and ammonium persulfate.

11. A rinse solution for passivation of a phase change alloy on a substrate surface used in conjunction with CMP polishing of the phase change alloy, the rinse solution initially comprising:
deionized water; and
at least one component in the deionized water, the component selected from the group consisting of polyethylene imine, polyethylene glycol, polyacrylic amide, alcohol ethoxylates, polyacrylic acid, an azole containing compound, benzo-triazole, and combinations thereof;
wherein the rinse solution has a pH between 2 and 12.

12. The rinse solution of claim 11, wherein the solution comprises 10 to 14 liters of deionized water with 300 milliliters of a component solution having 1% to 10% of component by weight.

13. A method for chemical-mechanical polishing (CMP) of a phase change alloy on a substrate surface, the method comprising:
positioning a substrate comprising a phase change alloy material on a platen containing a polishing pad;
delivering a polishing slurry to the polishing pad, the polishing slurry initially comprising:
colloidal particles with a particle size less than 60 nm and in an amount between 0.2% to about 10% by weight of the slurry;
a pH adjustor;
a chelating agent comprising at least one carboxylic acid;
an oxidizing agent in an amount less than 1% by weight of the slurry; and
polyacrylic acid;
polishing the substrate on the platen to remove a portion of the phase change alloy; and
rinsing the substrate on the platen with a rinse solution, the rinse solution initially comprising:
deionized water; and
at least one component in the deionized water, the component selected from the group consisting of polyethylene glycol, polyacrylic amide, polyethylene imine, an azole containing compound, benzo-triazole, and combinations thereof;
wherein the rinse solution has a pH between 2 and 12.

14. The method of claim 13, wherein rinsing the substrate is performed after polishing the substrate.

15. The method of claim 13, wherein the amount of polyacrylic acid is in an amount between 50 ppm and 5000 ppm.

16. The method according to claim 13, wherein the colloidal particles comprise silica or alumina.

17. The method according to claim 16, wherein the colloidal particles are modified silica with alumina or the alumina is surface coated.

18. The method according to claim 17, wherein the pH is between 5 and 7.

19. The method according to claim 13 further comprising H₃PO₄ in an amount between 50 ppm to 5000 ppm.

20. The method according to claim 13, wherein the organic carboxylic acid is selected from the group consisting of citric acid, oxalic acid, tartaric acid, and succinic acid, amino acids, salts thereof, and combinations thereof.

21. The method of claim 13, wherein the rinse solution comprises 10 to 14 liters of deionized water with 300 milliliters of a component solution having 1% to 10% of component by weight.

22. The method of claim 13, wherein the rinse duration is between 5 and 30 seconds.

23. The method of claim 13, wherein the oxidizing agent comprises at least one of the following: hydrogen peroxide, organic peroxide, potassium iodate, and ammonium persulfate.

24. The method of claim 13, further comprising cleaning the polishing pad with a pad cleaning solution, the cleaning solution comprising:
0.2-2% phosphoric acid, and;
0.2%-5% hydrogen peroxide.

25. The method of claim 24, wherein the cleaning the polishing pad further comprises:
delivering the pad cleaning solution onto the pad, where the pad rotates at 20 rpm or less;
soaking the pad for 30 seconds with the pad cleaning solution;
conditioning the pad for 20 seconds, and;
rinsing the pad with deionized water, where the pad rotates at 80 rpm or more.
